(19) United States
(12) Patent Application Publication
(10) Pub. No.: US 2026/0072348 A1
(43) Pub. Date: Mar. 12, 2026

(54) PHOTOCURING AGENTS

(71) Applicant: Merck Patent GmbH, Darmstadt (DE)

(72) Inventors: Andreas BERKEFELD, Darmstadt (DE); Sophia BUHBUT, Jerusalem (IL); Odelia SAADON, Jerusalem (IL); Roy SCHREIBER, Jerusalem (IL)

(73) Assignee: Merck Patent GmbH, Darmstadt (DE)

(21) Appl. No.: 19/324,227

(22) Filed: Sep. 10, 2025

(30) Foreign Application Priority Data
Sep. 11, 2024 (EP) 24199641.2

(51) Int. Cl. G03F 7/004; G02B 27/01; G02F 1/1335; G03F 7/075; G03F 7/16; H10H 29/01; H10H 29/80; H10H 29/855; H10K 59/80

(52) U.S. Cl. CPC G03F 7/0043; G02B 27/0172; G03F 7/0755; G03F 7/162; G02B 2207/101; G02F 1/1335; G02F 2202/36; H10H 29/0363; H10H 29/855; H10H 29/872; H10K 59/875

(57) ABSTRACT

A formulation for preparing an optical layer, preferably a particle-free optical layer, preferably to be used for nanoimprint lithography, more preferably to be used for direct UV nanoimprint lithography comprises compound A and a metal oxide precursor. Compound A is represented by the formula:
X (NO₂⁻)ₙ, wherein X and n are defined herein. The formulation may exhibit at least one of properties as an advanced material or as a high performance material. The formulation may be used in the nanotechnology process to make semiconductor device/display device application, for example semiconductor chip, or a liquid crystal, quantum dot, OLED display fabricated on a substrate controlled by semiconductors.

The present application relates to formulations for preparing an optical layer, uses of the formulations for preparing an optical layer, methods for preparing an optical layer, optical layers, methods for producing a patterned optical layer, patterned optical layers, optical devices, and display devices.

### BACKGROUND OF THE INVENTION

Materials with high refractive index and low absorbance across the visible spectral region are of particular interest for making optical devices such as diffractive gratings. In this context, (nano)particle-free photocurable nanoimprint lithography (NIL) is a preferred method for patterning optical materials. For this purpose, the materials need to be liquid at or close to room temperature and cured under UV light, preferably at industrially common wavelengths such as 365 nm.

Takeda et al., 2017, Hydroxyl radical generation with a high power ultraviolet light emitting diode (UV-LED) and application for determination of hydroxyl radical reaction rate constants, studies a simple, efficient and selective hydroxyl radical generation system based on the photolysis of submicromolar concentrations of nitrite using a high-power ultraviolet light emitting diode (UV-LED).

Rhaman et al., 2022, Nb₂O₅, LiNbO₃, and (Na, K)NbO₃ Thin Films from High-Concentration Aqueous Nb-Polyoxometalates, studies Nb-polyoxometalate (Nb-POM) speciation in enabling deposition of Nb₂O₅, LiNbO₃, and (Na, K)NbO₃ (KNN) from high-concentration solutions, up to 2.5 M Nb for Nb₂O₅ and ˜1 M Nb for LiNbO₃ and KNN.

Cardineau et al., 2014, Photolithographic properties of tin-oxo clusters using extreme ultraviolet light (13.5 nm), studies the photolysis of tin clusters of the type [(RSn)₁₂O₁₄(OH)₆] X₂ using extreme ultraviolet (EUV, 13.5 nm) light, and developed these clusters into novel high-resolution photoresists.

### SUMMARY OF THE INVENTION

The inventors newly have found that there are still one or more of considerable problems for which improvement is desired, as listed below:
preparing an optical layer using a formulation without a compound that generates a proton; preparing an optical layer using a formulation comprising a metal oxide precursor with a ligand and an additional compound that is sufficiently soluble or miscible in the liquid metal oxide precursor and is capable of generating radicals under thermal conditions or UV irradiation; preparing an optical layer using a formulation comprising a metal oxide precursor with a ligand and an additional compound that is sufficiently soluble or miscible in the metal oxide precursor in a solvent and capable of generating radicals under thermal conditions or UV irradiation; preparing an optical layer using a formulation comprising a metal oxide precursor with a ligand and an additional compound that is sufficiently soluble or miscible in the liquid metal oxide precursor and the metal oxide precursor in a solvent and capable of generating radicals under thermal conditions or UV irradiation; preparing an optical layer comprising a material which provides a sufficiently high refractive index after curing; preparing a dense, crack-less or crack-free optical layer; preparing an optical layer comprising a metal oxide precursor, which is well dispersed in the formulation; realizing a more stable formulation; zero or reduced viscosity change of the formulation; providing suitable formulation for wet printing, namely for spin-coating or ink jetting, realizing continuous inkjet printing, preparing an optical layer suitable for nanoimprint lithography, preparing an optical layer suitable for particle-free nanoimprint lithography.

The inventors aimed to solve one or more of the above-mentioned problems. Then, the present inventors have surprisingly found that one or more of the above-described technical problems can be solved by the features as defined in the claims.

Namely, it is found a new formulation for preparing an optical layer, preferably a particle-free optical layer, preferably to be used for nanoimprint lithography, more preferably to be used for direct UV nanoimprint lithography, comprising compound A and a metal oxide precursor,
wherein the compound A is represented by formula (a1);

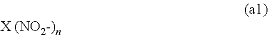

wherein X is a cation, preferably a monovalent, divalent, or trivalent cation, more preferably a monovalent cation;
when X is a monovalent cation, n is 1; when X is a divalent cation, n is 2; when X is a trivalent cation, n is 3;
wherein the metal oxide precursor comprises a group 4, 5, 6, 8, 11, 12, 14 or 15 metal element of the periodic table, more preferably a group 4, 5 or 12 metal element of the periodic table, a ligand and optionally one or more other organic components or substituents and/or one or more other inorganic components.

In another aspect, the invention further relates to use of the formulation of the present invention for preparing an optical layer, preferably a particle-free optical layer, preferably to be used for nanoimprint lithography, more preferably to be used for direct UV nanoimprint lithography.

In another aspect, the invention furthermore relates to a method for preparing an optical layer containing a metal oxide, preferably a particle-free optical layer containing a metal oxide, preferably to be used for nanoimprint lithography, more preferably to be used for direct UV nanoimprint lithography, comprising the following step (i);
(i) coating the formulation of the present invention above a substrate to form an optical layer, preferably the substrate is a silicon wafer; preferably by spin-coating, more preferably by spin-coating with 500 to 6,000 RPM for 5 to 100 seconds, very preferably by spin-coating with 1,000 to 5,000 RPM for 10 to 70 seconds, most preferably spin-coating with 1,500 to 4,500 RPM for 15 to 50 seconds.

In another aspect, the invention furthermore relates to an optical layer, preferably a particle-free optical layer, preferably to be used for nanoimprint lithography, more preferably to be used for direct UV nanoimprint lithography, produced by the method of the present invention, wherein the thickness of the optical layer is in the range from 1 to 700 nm, preferably from 3 to 600 nm, more preferably 5 to 500 nm, very preferably 7 to 400 nm.

In another aspect, the invention furthermore relates to a method for producing a patterned optical layer comprising the following steps (iv) and (v);
(iv) producing an optical layer by the method of the present invention,
(v) forming a pattern by pressing a mold onto the optical layer,
(vi) optionally, heating the patterned optical layer, preferably at 35 to 200° C. for 1 to 100 minutes, more preferably at 40 to 150° C. for 1 to 50 minutes, very preferably at 45 to 100° C. for 1 to 20 minutes,
(vii) optionally, irradiating light to the patterned optical layer, preferably the light is UV, preferably the light intensity is in the range from 150 to 500 mW/cm², more preferably 200 to 400 mW/cm², very preferably 250 to 350 mW/cm²; preferably the wavelength of the light is in the range from 100 to 500 nm, more preferably 250 to 450 nm, very preferably 350 to 400 nm; preferably the irradiation time is in the range from 1 to 120 minutes, preferably from 5 to 100 minutes, more preferably 7 to 75 minutes.

In another aspect, the invention furthermore relates to a patterned optical layer produced by the method of the present invention.

In another aspect, the invention furthermore relates to an optical device comprising the patterned optical layer of the present invention and a substrate.

In another aspect, the invention furthermore relates to a display device comprising at least one functional medium configured to direct and modulate a light or configured to emit light; and the patterned optical layer of the present invention, or the optical device of the present invention.

### Technical Effects of the Invention

The present invention may provide one or more of following effects; preparing an optical layer using a formulation without a compound that generates a proton; preparing an optical layer using a formulation comprising a metal oxide precursor with a ligand and an additional compound that is sufficiently soluble or miscible in the liquid metal oxide precursor and capable of generating radicals under thermal conditions or under UV irradiation; preparing an optical layer using a formulation comprising a metal oxide precursor with a ligand and an additional compound that is sufficiently soluble or miscible in the metal oxide precursor in a solvent and capable of generating radicals under thermal conditions or under UV irradiation; preparing an optical layer using a formulation comprising a metal oxide precursor with a ligand and an additional compound that is sufficiently soluble or miscible in the liquid metal oxide precursor and the metal oxide precursor in a solvent and capable of generating radicals under thermal conditions or under UV irradiation; preparing an optical layer comprising a material which provides a sufficiently high refractive index after curing; preparing a dense, crack-less or crack-free optical layer; preparing an optical layer comprising a metal oxide precursor, which is well dispersed in the formulation; realizing a more stable formulation; zero or reduced viscosity change of the formulation; providing suitable formulation for wet printing, namely for spin-coating or ink jetting, realizing continuous inkjet printing, preparing an optical layer suitable for nanoimprint lithography, preparing an optical layer suitable for direct UV nanoimprint lithography.

### BRIEF DESCRIPTION OF DRAWINGS

FIG. 1: shows the UV/visible spectrum of the filtrates of Example 1 irradiated with 365 nm UV with 300 mW/cm² for 0, 10 and 60 minutes respectively.

FIG. 2: shows the UV/visible spectrum of the filtrates of Example 2 irradiated with 365 nm UV with 300 mW/cm² for 0 and 60 minutes respectively.

FIG. 3: shows the thermal gravimetric analysis of the solution of Example 3.

FIG. 4: shows the UV/visible spectrum of the filtrates of Comparative example 1 irradiated with 365 nm UV with 300 mW/cm² for 0, 10 and 60 minutes respectively.

FIG. 5: shows the thermal gravimetric analysis of the solution of Comparative example 2.

### DEFINITION OF THE TERMS

In the context of the present invention, the term “ligand” as used herein, refers to an ion or molecule attached to a metal atom by coordinate bonding.

The term “formulation medium” or the plural term “formulation media” as used herein, denote one or more compounds serving as a solvent, suspending agent, carrier and/or matrix for the metal oxide precursor compound and any other component included in the formulation. Formulation media are generally inert compounds that do not react with said metal oxide precursor compounds and said other components. Formulation media may be liquid compounds, solid compounds or mixtures thereof. Typically, formulation media are organic compounds.

The term “surfactant” as used herein, refers to an additive that reduces the surface tension of a given formulation.

The term “wetting and dispersion agent” as used herein, refers to an additive that increases the spreading and filling properties of a given formulation. In this way, the tendency of the molecules to adhere to each other is reduced.

The term “adhesion promoter” as used herein, refers to an additive that increases the adhesion of a given formulation.

The term “polymer matrix” as used herein, refers to an additive that acts as a macromolecular matrix for one or more components of a given formulation.

The term “optical layer” as used herein, refers to a layer of an intermediate. Nanostructure may be formed by pressing a mold onto said layer as the method of the present invention below shows.

The term “optical device” as used herein, relates to a device containing one or more optical components for forming a light beam including, but not limited to, gratings, lenses, prisms, mirrors, optical windows, filters, polarizing optics, UV and IR optics, and optical coatings. Preferred optical devices in the context of the present invention are augmented reality (AR) glasses and/or virtual reality (VR) glasses, mixed reality (MR) glasses.

The term “display device” as used herein, is a kind of an optical device configured to output/present information in visual or tactile form. Examples are Liquid crystal display (LCD), Light emitting diode display (LED display), organic light emitting display (OLED), micro-LED display, quantum dot display (QLED), AR display, VR display, MR display, plasma (PDP) display, electroluminescent (ELD) display.

### DETAILED DESCRIPTION OF THE INVENTION

Hereinafter, embodiments of the present invention are described in detail.

### [Formulation for Preparing an Optical Layer]

The formulation for preparing an optical layer, preferably a particle-free optical layer, preferably to be used for nanoimprint lithography, more preferably to be used for direct UV nanoimprint lithography, according to the present invention (hereafter referred to as the formulation) comprises, essentially consists of, compound A and a metal oxide precursor,
wherein the compound A is represented by formula (a1);

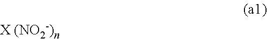

wherein X is a cation, preferably a monovalent, divalent, or trivalent cation, more preferably a monovalent cation;
when X is a monovalent cation, n is 1; when X is a divalent cation, n is 2; when X is a trivalent cation, n is 3;
wherein the metal oxide precursor comprises a group 4, 5, 6, 8, 11, 12, 14 or 15 metal element of the periodic table, more preferably a group 4, 5 or 12 metal element of the periodic table, a ligand and optionally one or more other organic components or substituents and/or one or more other inorganic components.

### [Compound A]

The formulation comprises the compound A represented by formula (a1);

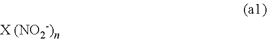

wherein X is a cation, preferably a monovalent, divalent, or trivalent cation, more preferably a monovalent cation;
when X is a monovalent cation, n is 1; when X is a divalent cation, n is 2; when X is a trivalent cation, n is 3.

It is believed that the 365 nm UV irradiation triggers decomposition of compound A from an electronically excited state which releases an equivalent amount of a radical species. The radical initiates a radical chain reaction that results in the eventual degradation of at least one of the ligands of the metal oxide precursor to generate a metal oxide.

In a preferable embodiment, X of the formula (a1) is a monovalent cation represented by formula (a2-1) or (a2-2);

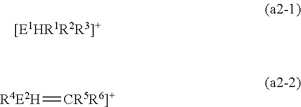

wherein E¹ and E² are each independently N or P, preferably N; R¹, R², R³, R⁴, R⁵ and R⁶ are each independently H, a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms; or —NR⁷R⁸;
when R¹, R², R³, R⁴, R⁵ and R⁶ are each independently an alkyl or an aryl, one or more non-adjacent CH₂ may each be replaced by O, S, CO, CO—O, O—CO, O—CO—O, CR⁷═CR⁸, or C≡C;
R⁷ and R⁸ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms; and
when R¹, R², R³, R⁴, R⁵, R⁶, R⁷ and R⁸ are each independently an alkyl or an aryl, one or more H may each be replaced by OH, COOH, a straight-chain alkyl having 1 to 6 carbon atoms, or a branched or cyclic structure-containing alkyl having 3 to 6 carbon atoms.

It is believed that the 365 nm UV irradiation more effectively triggers degradation of compound A from an electronically excited state which releases an equivalent amount of a radical species when the cation of the compound A has a structure represented by the formula (a2-1) or (a2-2). The radical initiates a radical chain reaction that results in the eventual degradation of at least one of the ligands of the metal oxide precursor to generate a metal oxide.

In a more preferable embodiment, X of the formula (a1) is a cation represented by formula (a3);

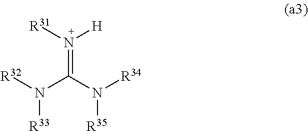

wherein R³¹, R³², R³³, R³⁴ and R³⁵ are each independently H, a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms; preferably R³¹, R³², R³³, R³⁴ and R³⁵ are H; when R³¹, R³², R³³, R³⁴ and R³⁵ are each independently an alkyl or an aryl, one or more non-adjacent CH₂ may each be replaced by O, S, CO, CO—O, O—CO, O—CO—O, CH═CH, or C≡C;
when R³¹, R³², R³³, R³⁴ and R³⁵ are each independently an alkyl or an aryl, one or more H may each be replaced by OH, COOH, a straight-chain alkyl having 1 to 6 carbon atoms, or a branched or cyclic structure-containing alkyl having 3 to 6 carbon atoms.

It is believed that 365 nm UV irradiation furthermore effectively triggers degradation of compound A from an electronically excited state which releases an equivalent amount of a radical species when the cation of the compound A has a structure represented by the formula (a3). The radical initiates a radical chain reaction that results in the eventual degradation of at least one of the ligands of the metal oxide precursor to generate a metal oxide.

Examples of the compound A include NH₄⁺NO₂⁻, NH₃CH₃⁺NO₂⁻, NH₂(CH₃)₂⁺NO₂⁻, NH(CH₃)₃⁺NO₂⁻, PH₄⁺NO₂⁻, PH₃CH₃⁺NO₂⁻, PH₂(CH₃)₂⁺NO₂⁻, PH(CH₃)₃⁺NO₂⁻, NH₂═C(NH₂)₂⁺NO₂⁻, NH₂═CH(NH₂)⁺NO₂⁻, NH₂═C(CH₃)NH₂⁺NO₂⁻ and NH₂═C(CH₃)₂⁺NO₂⁻.

The formulation may either comprise one kind of the compound A or two or more kinds of the compound A having different structures from each other. The formulation preferably comprises one kind of compound A.

The mole ratio of the compound A to the metal oxide precursor may be in the range from 0.6NA to 1.4NA, preferably 0.7NA to 1.3NA, more preferably 0.75NA to 1.2NA, very preferably 0.80NA to 1.1NA, where NA represents the number of ligands contained in one metal oxide precursor.

It is believed that 365 nm UV irradiation furthermore effectively triggers degradation of compound A from an electronically excited state which releases an equivalent amount of a radical species when the mole ratio of the compound A to the metal oxide precursor is in the above-mentioned range. The radical initiates a radical chain reaction that results in the eventual degradation of at least one of the ligands of the metal oxide precursor to generate a metal oxide.

### [Metal Oxide Precursor]

The formulation comprises the metal oxide precursor comprising a group 4, 5, 6, 8, 11, 12, 14 or 15 metal element of the periodic table, more preferably a group 4, 5 or 12 metal element of the periodic table, a ligand and optionally one or more other organic components or substituents and/or one or more other inorganic components.

In a preferable embodiment, the metal oxide precursor is represented by any one of formulae (m2-1) to (m2-5), preferably formula (m2-1), (m2-3) or (m2-4);

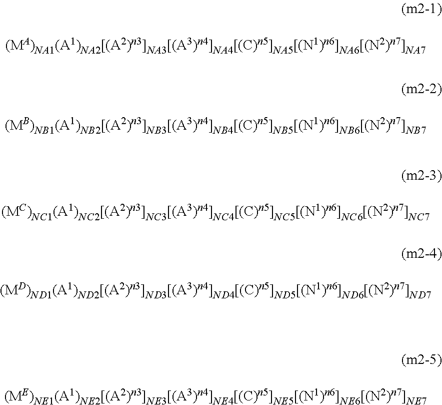

wherein
M^{A} is Cu, Zn or Bi, preferably Zn,
M^{B} is Al,
M^{C} is Pb, Sn or Ti, preferably Ti,
M^{D} is Nb or V, preferably Nb,
M^{E} is Fe, Cr, Mo or W;
A¹ is the ligand represented by formula (m3);
A², A³, C, N¹ and N² are each independently a group of one or more atoms;
n3, n4 n5, n6 and n7 represent a valence of A², A³, C, N¹ and N² respectively;
n3 and n4 are each independently 1− to 5−, more preferably 1− to 3−;
n5 is 1+ to 5+, more preferably 1+ to 3+;
n6 and n7 are 0;
NA1, NB1, NC1, ND1 and NE1 are each independently 1 to 50, preferably 2 to 45;
NA2, NB2, NC2, ND2 and NE2 are each independently 1 to 55, preferably 1 to 50;
NA3, NB3, NC3, ND3, NE3, NA4, NB4, NC4, ND4 and NE4 are each independently 0 to 80, preferably 0 to 70, more preferably 0 to 65;
NA5, NB5, NC5, ND5 and NE5 are each independently 0 to 20, preferably 0 to 15, more preferably 0 to 10;
NA6, NB6, NC6, ND6, NE6, NA7, NB7, NC7, ND7 and NE7 are each independently 0 to 40, preferably 0 to 30, more preferably 0 to 20;
provided that

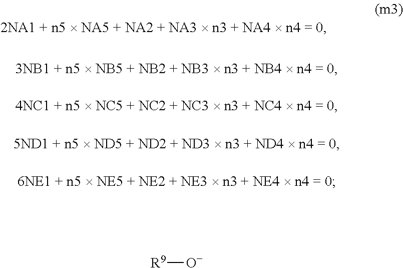

wherein R⁹ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms; an aryl-alkylene having 6 to 25 carbon atoms, preferably from 6 to 15 carbon atoms, more preferably 6 to 10 carbon atoms;
wherein one or more non-adjacent CH₂ may each be replaced by O, S, CO, CO—O, O—CO, O—CO—O, CR¹⁰═CR¹¹, or C≡C, preferably replaced by CO, CO—O, O—CO, or O—CO—O, more preferably CO;
R¹⁰ and R¹¹ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms,
preferably 3 to 15 carbon atoms, more preferably 3 to 10 carbon atoms; an aryl having 6 to 25 carbon atoms, preferably 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms.

It is believed that 365 nm UV irradiation more effectively triggers degradation of compound A from an electronically excited state which releases an equivalent amount of a radical species when the metal oxide precursor is represented by any one of the formulae (m2-1) to (m2-5). The radical initiates a radical chain reaction that results in the eventual degradation of at least one of the ligands of the metal oxide precursor to generate a metal oxide.

In a more preferable embodiment, the metal oxide precursor is represented by any one of formulae (m4-1) to (m4-5), preferably formula (m4-1), (m4-3) or (m4-4);

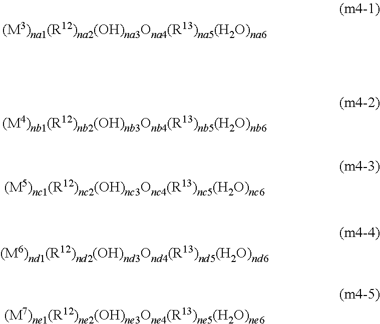

wherein
na1, nb1, nc1, nd1, and ne1 are each independently 1 to 50, preferably 2 to 45; na2, nb2, nc2, nd2, and ne2 are each independently 1 to 55, preferably 1 to 50; na3, nb3, nc3, nd3, and ne3 are each independently 0 to 20, preferably 0 to 10, more preferably 0 to 5; na4, nb4, nc4, nd4, and ne4 are each independently 1 to 80, preferably 1 to 70, more preferably 1 to 65; na5, nb5, nc5, nd5, and ne5 are each independently 0 to 20, preferably 0 to 10, more preferably 0 to 5; na6, nb6, nc6, nd6, and ne6 are each independently 0 to 20, preferably 0 to 10, more preferably 0 to 5;
provided that 2na1=na2+na3+2na4, 3nb1=nb2+nb3+2nb4, 4nc1=nc2+nc3+2nc4, 5nd1=nd2+nd3+2nd4, 6ne1=ne2+ne3+2ne4;
M³ is Cu, Zn or Bi, preferably Zn,
M⁴ is Al,
M⁵ is Pb, Sn or Ti, preferably Ti,
M⁶ is Nb or V, preferably Nb,
M⁷ is Fe, Cr, Mo or W;
R¹² is the ligand represented by formula (m5), and R¹³ is an acid;

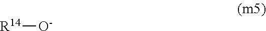

wherein R¹⁴ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl-alkylene having 6 to 25 carbon atoms, preferably 6 to 15 carbon atoms, more preferably 6 to 10 carbon atoms;
wherein one or more non-adjacent CH₂ may each be replaced by O, S, CO, CO—O, O—CO, O—CO—O, CR¹⁵═CR¹⁶, or C≡C, preferably replaced by CO, CO—O, O—CO, or O—CO—O, more preferably CO;
R¹⁵ and R¹⁶ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms.

It is believed that 365 nm UV irradiation furthermore effectively triggers degradation of compound A from an electronically excited state which releases an equivalent amount of a radical species when the metal oxide precursor is represented by any one of the formulae (m4-1) to (m4-5). The radical initiates a radical chain reaction that results in the eventual degradation of at least one of the ligands of the metal oxide precursor to generate a metal oxide.

In a furthermore preferable embodiment, R¹³ is an acid represented by formula (m6);

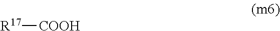

wherein R¹⁷ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms; wherein one or more non-adjacent CH₂ may each be replaced by O, S, CO, CO—O, O—CO, O—CO—O, CR¹⁸═CR¹⁹, or C≡C;
R¹⁸ and R¹⁹ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms.

It is believed that 365 nm UV irradiation furthermore effectively triggers degradation of compound A from an electronically excited state which releases an equivalent amount of a radical species when the metal oxide precursor contains an acid represented by the formula (m6). The radical initiates a radical chain reaction that results in the eventual degradation of at least one of the ligands of the metal oxide precursor to generate a metal oxide.

In another furthermore preferable embodiment, the metal oxide precursor comprises the ligand represented by the formula (m51);

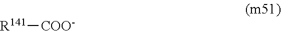

wherein R¹⁴¹ is a straight-chain alkyl having 1 to 20 carbon atoms, preferably 1 to 10 carbon atoms, more preferably 5 to 10 carbon atoms; a branched or cyclic structure-containing alkyl having 3 to 20 carbon atoms, preferably 3 to 10 carbon atoms, more preferably 5 to 10 carbon atoms; an aryl having 6 to 20 carbon atoms, preferably 6 to 15 carbon atoms, more preferably 6 to 10 carbon atoms; wherein one or more H may each be replaced by OH, COOH, a straight-chain alkyl having 1 to 6 carbon atoms, or a branched or cyclic structure-containing alkyl having 3 to 6 carbon atoms.

It is believed that one or more of the ligands of the metal oxide precursor get removed further easily by the radical generated by irradiating the compound A when the ligand is represented by the formula (m51).

Examples of the metal oxide precursor include Zn₄O(2-ethylhexanoate)₆, Ti₄₄(OH)₄O₆₂(2-ethylhexanoic acid)₄(2-ethylhexanoate)₄₈(H₂O)₂, Al₃₂(benzoate)₃₆(OiPr)₄₀₂₈, (NH₄)₆[Bi₆O₄(citrate)₃(H₂O)₃], Zn₆(OH₂)(O₂CtBu)₈(pyridine-2,6-dimethanol), Ti₁₆(OH)₂O₂₀(propionic acid)₂₀(O^{t}Bu)₂, Sn₆O₆(O^{t}Bu)₆(OAc)₆, Nb₈O₁₂(2-naphthoate)₁₂(OEt)₄, [Mo₃O₂(OAc)₆(H₂O)₃]²⁺, [W₃O₂(O₂CC₆H₅)₆(H₂O)₃]²⁺.

The ligand stabilizes the remainder of the metal oxide precursor.

It is believed that the optical layer containing the metal oxide is formed by the removal of one or more ligands of the metal oxide precursor in a radical chain reaction by the radicals generated by UV irradiation of the compound A. The following formula represents an example of a considered reaction with said removal.

Zn₄O(O₂CR)₆+6GdnHNO₂→4ZnO+6Gdn+6NO+6CO₂+3H₂O+3R₂.

In the formula above, “Gdn” is guanidinium, the compound A is GdnHNO₂, the metal oxide precursor is Zn₄O(O₂CR)₆, the ligand is O₂CR.

The formulation may either comprise one kind of the metal precursor or two or more kinds of the metal precursor having different structures from each other. The formulation preferably comprises one kind of the metal precursor.

The formulation may comprise one or more metal oxide precursors that are not represented by any one of the formulae (m2-1) to (m2-5). When the total molar amount of the metal oxide precursor(s) represented by any one of the formulae (m2-1) to (m2-5) contained in the formulation is nm and the total molar amount of the whole metal oxide precursor(s) contained in the formulation is nₜₒₜₐₗ, nₘ/nₜₒₜₐₗ preferably equals 0.8-1 or nₘ/nₜₒₜₐₗ×100 preferably equals 80 to 100%, more preferably 0.9-1 or 90 to 100%, and even more preferably 0.95-1 or 95 to 100%. It is also a preferred embodiment that all the metal oxide precursor(s) contained in the formulation are represented by the formulae (m2-1) to (m2-5) (nₘ/nₜₒₜₐₗ=100%).

### [Solvent]

The formulation may further comprise a solvent. The solvent is selected from one or more members of the group consisting of a secondary linear or branched ≥C3 alcohol, preferably it is selected from isopropanol, 2-butanol, 2-pentanol, 3-pentanol, propylene glycol monoalkyl ethers, preferably it is propylene glycol monomethyl ether, propylene glycol monoethyl ether and/or propylene glycol monopropyl ether, propylene glycol monoalkyl ether acetates, preferably it is propylene glycol monomethyl ether acetate, propylene glycol dialkyl ethers, preferably it is propylene glycol dimethyl ether, and alkyl lactate, preferably it is ethyl lactate.

It is believed that both the compound A and the metal oxide precursor are sufficiently soluble in one of the above-described solvents.

The boiling point of the solvent is preferably in the range from 35 to 100° C., more preferably 40 to 90° C., very preferably 45 to 80° C.

It is believed that pre-baking after coating the formulation effectively removes the solvent.

When the formulation comprises the solvent, the solid content is preferably in the range from 0.1 to 20 mass parts, more preferably 0.5 to 15 mass parts, very preferably 0.8 to 10 mass parts based on 100 parts of the formulation.

The term “solid content” used herein refers to the total amount of all the components except for the solvent contained in the formulation.

### [Compound B]

The formulation may further comprise compound B comprising Si.

In a preferable embodiment, the compound B is represented by formula (c1).

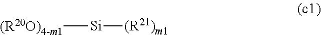

wherein m1 is 0, 1, 2 or 3, preferably 1;
R²⁰ is a straight-chain alkyl having 1 to 15 carbon atoms, preferably 1 to 10 carbon atoms, more preferably 1 to 5 carbon atoms, very preferably 1 to 3 carbon atoms; a branched or cyclic structure-containing alkyl having 3 to 15 carbon atoms, preferably 3 to 10 carbon atoms, more preferably 3 to 5 carbon atoms; an aryl having 6 to 20 carbon atoms, preferably 6 to 15 carbon atoms, more preferably 6 to 10 carbon atoms;
wherein one or more non-adjacent CH₂ may each be replaced by O, S, CO, CO—O, O—CO, O—CO—O, CR²²═CR²³, or C≡C;
R²² and R²³ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms;
wherein R²¹ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; a straight-chain alkenyl having 1 to 25 carbon atoms, preferably 1 to 15 carbon atoms, more preferably 1 to 10 carbon atoms; a branched or cyclic structure-containing alkenyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more non-adjacent CH₂ may each be replaced by O, S, CO, CO—O, O—CO, O—CO—O, CR²⁴═CR²⁵, C═CR²⁴R²⁵, or C≡C, preferably replaced by O—CO; wherein R²⁴ and R²⁵ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms, very preferably R²⁴ and R²⁵ are H;
wherein one or more H may each be replaced by OH, COOH, a straight-chain alkyl having 1 to 6 carbon atoms, or a branched or cyclic structure-containing alkyl having 3 to 6 carbon atoms.

It is believed that the compound B reacts with the metal oxide precursor to form metal oxide nanoparticles covered with ligands containing Si. 365 nm UV irradiation triggers degradation of compound A from an electronically excited state to release an equivalent amount of a radical species. The radical species initiates a radical chain reaction that eventually results in removal of at least one of the organic substituents at Si from the metal oxide nanoparticle.

The content of the compound B is preferably in the range from 7 to 50 mass parts, more preferably 10 to 40 mass parts, very preferably 15 to 30 mass parts based on 100 parts of the metal oxide precursor.

### [Acid]

The formulation may further comprise an acid selected from one or more members of the group consisting of sulfonic acids, hydrochloric acid and carboxylic acids, preferably hydrochloric acid.

It is believed that one or more of the above-described acids hydrolyze the compound B. The hydrolyzed compound B reacts with the metal oxide precursor to form nanoparticles covered by ligands containing Si.

### [Additives]

The formulation may optionally comprise one or more additives selected from surfactants, wetting and dispersion agents, adhesion promoters, and polymer matrices.

Or, in some embodiments, the formulation of the present invention does not contain any additives.

### [Use]

In another aspect, the present invention also relates to use of the formulation of the present invention for preparing an optical layer, preferably a particle-free optical layer, preferably to be used for nanoimprint lithography, more preferably to be used for direct UV nanoimprint lithography.

### [Method for Preparing an Optical Layer Containing a Metal Oxide]

In another aspect, the present invention also relates to a method (hereafter referred to as the method) for preparing an optical layer containing a metal oxide, preferably a particle-free optical layer containing a metal oxide, preferably to be used for nanoimprint lithography, more preferably to be used for direct UV nanoimprint lithography, comprising the following step (i);
(i) coating the formulation of the present invention above a substrate to form an optical layer, preferably the substrate is a silicon wafer or glass, more preferably glass; preferably by spin-coating, more preferably by spin-coating with 500 to 6,000 RPM for 5 to 100 seconds, very preferably by spin-coating with 1,000 to 5,000 RPM for 10 to 70 seconds, most preferably spin-coating with 1,500 to 4,500 RPM for 15 to 50 seconds.

In a preferable embodiment, the method may further comprise the following step (ii);
(ii) heating the optical layer at 35 to 200° C. for 1 to 100 minutes, preferably at 40 to 150° C. for 1 to 50 minutes, more preferably at 45 to 100° C. for 1 to 20 minutes.

The step (ii) may be carried out under air atmosphere, atmospheres with increased noble gas content or atmospheres with increased N₂ content, preferably under air atmosphere or atmospheres with increased noble gas content, more preferably under air atmosphere or atmospheres with increased argon content.

The step (ii) may serve the purpose to remove the excessive solvent in the formulation.

In a more preferable embodiment, the method may further comprise the following step (iii);
(iii) irradiating light to the optical layer, preferably the light is UV; preferably the light intensity is in the range from 150 to 500 mW/cm², more preferably 200 to 400 mW/cm², very preferably 250 to 350 mW/cm²; preferably the wavelength of the light is in the range from 100 to 500 nm, more preferably 250 to 450 nm, very preferably 350 to 400 nm; preferably the irradiation time is in the range from 1 to 120 minutes, preferably 5 to 100 minutes, more preferably 7 to 75 minutes.

The step (iii) may serve the purpose to convert the metal oxide precursor or metal oxide precursor mixture layers on the substrate into a metal oxide layer. Moreover, the final properties of the metal oxide layer may be adjusted by the step (iii).

### [Optical Layer]

In another aspect, the present invention also relates to an optical layer, preferably a particle-free optical layer, preferably to be used for nanoimprint lithography, more preferably to be used for direct UV nanoimprint lithography produced by the method of the present invention.

The thickness of the optical layer is in the range from 1 to 700 nm, preferably from 3 to 600 nm, more preferably 5 to 500 nm, very preferably 7 to 400 nm.

### [Method for Producing a Patterned Optical Layer]

In another aspect, the present invention also relates to a method for producing a patterned optical layer comprising the following steps (iv) and (v);
(iv) producing an optical layer by the method,
(v) forming a pattern by pressing a mold onto the optical layer,
(vi) optionally, heating the patterned optical layer, preferably at 35 to 200° C. for 1 to 100 minutes, more preferably at 40 to 150° C. for 1 to 50 minutes, very preferably at 45 to 100° C. for 1 to 20 minutes,
(vii) optionally, irradiating light to the patterned optical layer, preferably the light is UV, preferably the light intensity is in the range from 150 to 500 mW/cm², more preferably 200 to 400 mW/cm², very preferably 250 to 350 mW/cm²; preferably the wavelength of the light is in the range from 100 to 500 nm, more preferably 250 to 450 nm, very preferably 350 to 400 nm; preferably the irradiation time is in the range from 1 to 120 minutes, preferably from 5 to 100 minutes, more preferably 7 to 75 minutes.

### [Patterned Optical Layer]

In another aspect, the present invention also relates to a patterned optical layer produced by the method of the present invention.

### [Optical Device]

In another aspect, the present invention also relates to optical device comprising the patterned optical layer of the present invention and a substrate.

The substrates are preferably made of inorganic or organic base materials, more preferably inorganic base materials. The inorganic base materials include materials selected from the group consisting of ceramics, glass, fused silica, sapphire, silicon, silicon nitride and quartz. The geometry of the substrate is not specifically limited, however, preferred are sheets or wafers.

### [Display Device]

Finally, the present invention relates to display device comprising at least one functional medium configured to modulate a light or configured to emit light; and the patterned optical layer of the present invention, or the optical device of the present invention.

Examples of said display device is selected from a Liquid crystal display (LCD), Light emitting diode display (LED display), organic light emitting display (OLED), micro-LED display, quantum dot display (QLED), Augmented Reality (AR) hardware, Virtual Reality (VR) hardware, Mixed Reality (MR) hardware, plasma (PDP) display and an electroluminescent (ELD) display. Said AR, VR and MR hardware are also called as AR, VR and MR display. Preferably said display device is AR hardware, VR hardware or MR hardware.

The present invention is further illustrated by the examples following hereinafter which shall in no way be construed as limiting. The skilled person will acknowledge that various modifications, additions and alternations may be made to the invention without departing from the spirit and scope of the invention as defined in the appended claims.

### WORKING EXAMPLES

### Analytics and Measurement Methods

Ellipsometry is used to determine layer thickness, refractive index (n) and absorption index (k) of a metal oxide layer. Measurements are performed using an ellipsometer M2000 from J. A. Woolam and three different angles of incidence (65°, 70° and 75°). The measurement data is analyzed with software CompleteEase from J. A. Woolam, applying a Gen-Osc fitting model for obtaining refractive index (n) as well as absorption index (k). The optical constants are averaged from five measured points on each wafer.

All chemicals for synthesis described are purchased from Sigma Aldrich and used without further purification, unless differently mentioned elsewhere.

UV/vis measurements are performed using a Cary 7000 spectrometer from Agilent. UV LED irradiation is performed by an in-house built 365 LED source.

### Example 1

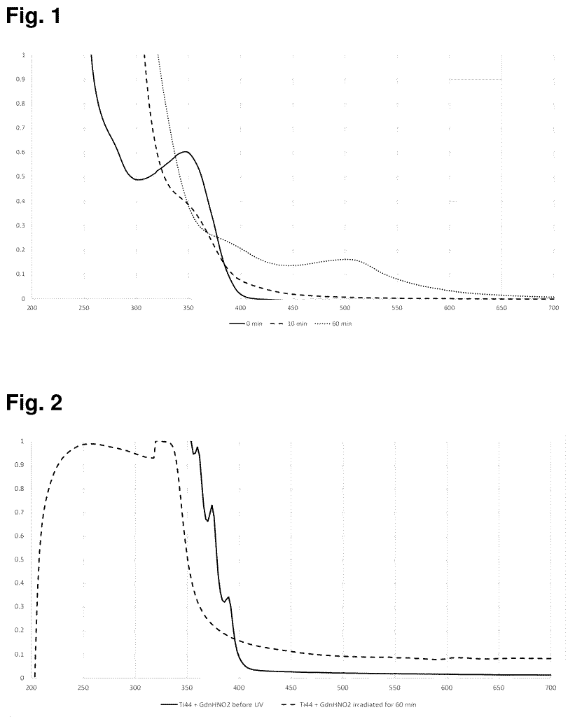

122.5 mg of Zn₄O(2-ethylhexanoate)₆ and 58.8 mg of guanidinium nitrite are dissolved in 2.45 mL of isopropanol. The solution is irradiated with 300 mW/cm² of a 365 nm UV LED for 0, 10 and 60 minutes. A precipitate is formed during the irradiation and is filtered off. A UV/visible spectrum is recorded of the filtrate at all the three irradiation times. The recorded UV/visible spectrum is shown by FIG. 1.

### Example 2

A solution prepared from 100 mg of Ti₄₄(OH)₄O₆₂(2-ethylhexanoic acid)₄(2-ethylhexanoate)₄₈(H₂O)₂ and 50 mg of guanidinium nitrite are dissolved in 2 mL of isopropanol. The solution is irradiated for 0 and 60 minutes with 300 mW/cm² of a 365 nm UV LED. A precipitate is formed during the irradiation and is filtered off. A UV/visible spectrum is recorded of the filtrate. The recorded UV/visible spectrum is shown by FIG. 2.

### Example 3

27 mg of Zn₄O(2-ethylhexanoate)₆ and 12 mg of guanidinium nitrite are dissolved in 540 μL of isopropanol. A 100 μL portion of this solution is transferred to a thermal gravimetric analysis (TGA) crucible and dried at 60° C.

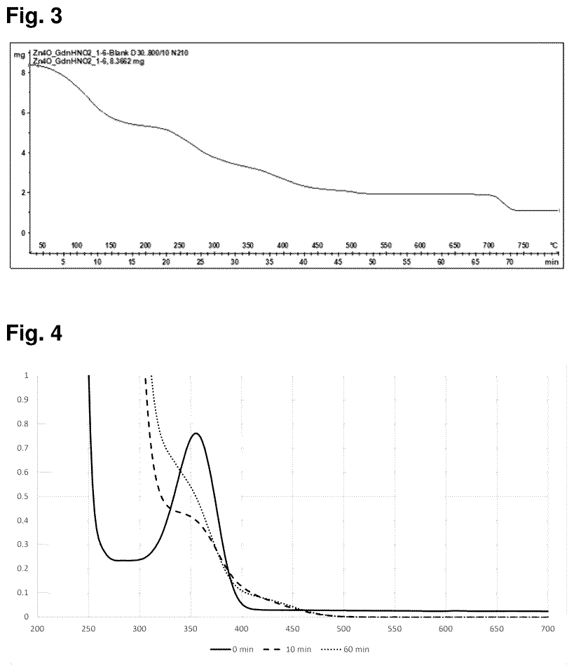

The residual mass at 800° C. is 13% of the initial mass (mass loss is 86.9%). The residual mass is consistent with the formation of zinc oxide (theoretical mass loss 81.6%). The result of the TGA is shown by FIG. 3.

### Example 4

25 mg of Zn₄O(2-ethylhexanoate)₆ and 12 mg of guanidinium nitrite are dissolved in 0.5 mL of isopropanol. 100 μL of the solution is spin coated onto a precleaned 2-inch silicon wafer (4000 RPM, 25 sec.), baked at 60° C. for 3 min., and finally exposed to 365 nm light with 300 mW/cm² for 10 min. under ambient conditions affording a homogeneous film. The optical properties of the film are shown by Table 1.

TABLE 1

| Optical properties | Pre-bake (60° C.) | Curing@365 nm |
|---|---|---|
| Refractive index | 1.50 | 1.51 |
| Absorption (k value) | 4.74E−03 | 4.32E−03 |
| Film thickness (nm) | 369 | 357 |

### Example 5

25 mg of Zn₄O(2-ethylhexanoate)₆ and 12 mg of guanidinium nitrite are dissolved in 0.5 mL of isopropanol. 100 μL of the solution is spin coated onto a precleaned 2-inch silicon wafer (4000 RPM, 25 sec.), baked at 60° C. for 3 min. and finally exposed to 300 mW/cm² 365 nm light for 10 min. under an argon atmosphere affording a homogeneous film. The optical properties of the film are shown by Table 2.

TABLE 2

| Optical properties | Pre-bake (60° C.) | Curing@365 nm |
|---|---|---|
| Refractive index | 1.54 | 1.55 |
| Absorption (K value) | 1.22E−02 | 1.25E−02 |
| Thickness (nm) | 377 | 361 |

### Example 6A

25 mg of Ti₄₄(OH)₄O₆₂(2-ethylhexanoic acid)₄(2-ethylhexanoate)₄₈(H₂O)₂ and 12 mg or 24 mg of guanidinium nitrite are dissolved in 0.5 mL of PGME. 100 μL of the solution is spin coated onto oxygen activated 2″ silicon wafer (2000 RPM, 25 sec.) followed by baking at 60° C. for 5 minutes and photocuring with 300 mW/cm² at 365 nm for 10 minutes resulting in a homogeneous film. The optical properties of the film are shown by Table 3.

TABLE 3

| Optical properties | Pre-bake (60° C.) | Curing@365 nm |
|---|---|---|
| Refractive index | 1.63 | 1.64 |
| Absorption (k value) | 5.8E−04 | 6.38E−04 |
| Film thickness (nm) | 224 | 214 |

### Example 6B

25 mg of Ti₄₄(OH)₄O₆₂(2-ethylhexanoic acid)₄(2-ethylhexanoate)₄₈(H₂O)₂ and 12 mg or 24 mg of guanidinium nitrite are dissolved in 0.5 mL of PGME. 100 μL of the solution is spin coated onto oxygen activated 2-inch silicon wafer (2000 RPM, 25 sec.) followed by baking at 60° C. for 5 minutes and photocuring with 300 mW/cm² at 365 nm for 10 minutes resulting in a homogeneous film. The optical properties of the film are shown by Table 4.

TABLE 4

| Optical properties | Pre-bake (60° C.) | Curing@365 nm |
|---|---|---|
| Refractive index | 1.59 | 1.60 |
| Absorption (k value) | 5.93E−04 | 1.85 E−02 |
| Film thickness (nm) | 310 | 279 |

### Example 7

4.08 mL of octyltriethoxysilane is added to 650 mL of PGME in a 1 L round bottom flask. 5 mL of 2M HCl is added and the solution is stirred at room temperature for 20 h. 11.65 mL of niobium ethoxide is added and the solution is heated to 80° C. for 2 h while stirring. The resulting solution is concentrated by rotor evaporation to 30% w/w.

25 mg of guanidinium nitrite is dissolved in 15 mL of PGME. 3 mL of this solution is used to dissolve 100 μL of the 30% w/w PGME solution of Nb₂O₅ nanoparticles covered by octyl silane ligands. 100 μL of the resulting solution is spin-coated onto a 2-inch Si wafer at 4000 RPM for 25 seconds and then baked at 60° C. for 5 minutes to remove the solvent. The film is exposed to 300 mW/cm² 365 nm light for 15 min. The optical properties of the film are shown by Table 5.

TABLE 5

| Optical properties | Pre-bake (60° C.) | Curing@365 nm |
|---|---|---|
| Refractive index | 1.68 | 1.70 |
| Absorption (k value) | 8.23E−05 | 2.53E−05 |
| Film thickness (nm) | 27 | 25 |

### Example 8

1.55 mL of 3-(trimethoxysilyl)propyl methacrylate is added to 650 mL of PGME in a 1 L round bottom flask. 5 mL of 2M HCl is added and the solution is stirred at room temperature for 20 h. 11.65 mL of niobium ethoxide is added and the solution is heated to 80° C. for 2 h while stirring. The resulting solution is concentrated by rotor evaporation to 30% w/w.

25 mg of guanidinium nitrite is dissolved in 15 mL of PGME. 3 mL of this solution is used to dissolve 100 μL of the 30% w/w PGME solution of Nb₂O₅ nanoparticles covered by 3-methacryloxypropyl silane ligands. 100 μL of the resulting solution is spin-coated onto a 2-inch Si wafer at 4000 RPM for 25 seconds and then baked at 60° C. for 5 minutes to remove the solvent. The film is exposed to 300 mW/cm² 365 nm light for 15 min. The optical properties of the film are shown by Table 6.

TABLE 6

| Optical properties | Pre-bake (60° C.) | Curing@365 nm |
|---|---|---|
| Refractive index | 1.68 | 1.70 |
| Absorption (k value) | 8.23E−05 | 2.53E−05 |
| Film thickness (nm) | 27 | 25 |

### Comparative Example 1

An experiment is performed the same way as Example 1 except for not including Zn₄O(2-ethylhexanoate)₆ into the solution. The recorded UV/visible spectrum is shown by FIG. 4.

### Comparative Example 2

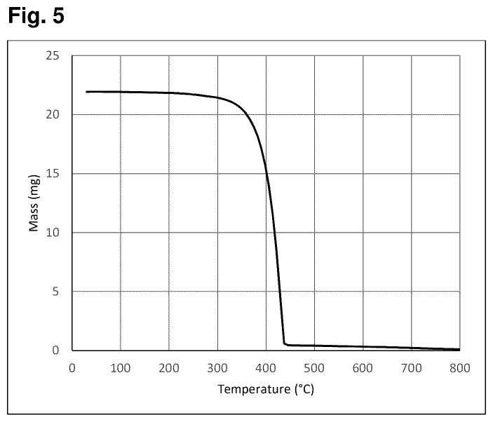

An experiment is performed the same way as Example 3 except for not including guanidinium nitrite into the solution. The result of TGA is shown by FIG. 5.

It is observed that Zn₄O(2-ethylhexanoate)₆ evaporates to the extent that its residual mass is less than 0.

1. A formulation for preparing an optical layer, preferably a particle-free optical layer, preferably to be used for nanoimprint lithography, more preferably to be used for direct UV nanoimprint lithography, comprising compound A and a metal oxide precursor,
wherein the compound A is represented by formula (a1); 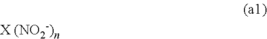
wherein X is a cation, preferably a monovalent, divalent, or trivalent cation, more preferably a monovalent cation;
when X is a monovalent cation, n is 1; when X is a divalent cation, n is 2; when X is a trivalent cation, n is 3;
wherein the metal oxide precursor comprises a group 4, 5, 6, 8, 11, 12, 14 or 15 metal element of the periodic table, more preferably a group 4, 5 or 12 metal element of the periodic table, a ligand and optionally one or more other organic components or substituents and/or one or more other inorganic components.

2. The formulation according to claim 1, wherein X is a monovalent cation represented by formula (a2-1) or (a2-2); 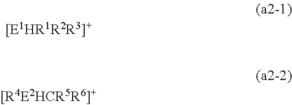
wherein
E¹ and E² are each independently N or P, preferably N;
R¹, R², R³, R⁴, R⁵ and R⁶ are each independently H, a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms; or —NR⁷R⁸;
when R¹, R², R³, R⁴, R⁵ and R⁶ are each independently an alkyl or an aryl, one or more non-adjacent CH₂ may each be replaced by O, S, CO, CO—O, O—CO, O—CO—O, CR⁷═CR⁸, or C≡C;
R⁷ and R⁸ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms; and
when R¹, R², R³, R⁴, R⁵, R⁶, R⁷ and R⁸ are each independently an alkyl or an aryl, one or more H may each be replaced by OH, COOH, a straight-chain alkyl having 1 to 6 carbon atoms, or a branched or cyclic structure-containing alkyl having 3 to 6 carbon atoms.

3. The formulation according to claim 2, wherein X is a cation represented by formula (a3); 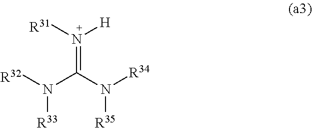
wherein
R³¹, R³², R³³, R³⁴ and R³⁵ are each independently H, a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms; preferably R³¹, R³², R³³, R³⁴ and R³⁵ are H;
when R³¹, R³², R³³, R³⁴ and R³⁵ are each independently an alkyl or an aryl, one or more non-adjacent CH₂ may each be replaced by O, S, CO, CO—O, O—CO, O—CO—O, CH═CH, or C≡C;
when R³¹, R³², R³³, R³⁴ and R³⁵ are each independently an alkyl or an aryl, one or more H may each be replaced by OH, COOH, a straight-chain alkyl having 1 to 6 carbon atoms, or a branched or cyclic structure-containing alkyl having 3 to 6 carbon atoms.

4. The formulation according to claim 1, wherein the metal oxide precursor is represented by any one of formulae (m2-1) to (m2-5); 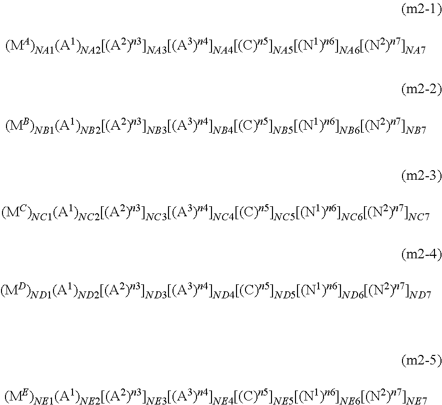
wherein
M^{A} is Cu, Zn or Bi, preferably Zn,
M^{B} is Al,
M^{C} is Pb, Sn or Ti, preferably Ti,
M^{D} is Nb or V, preferably Nb,
M^{E} is Fe, Cr, Mo or W;
A¹ is the ligand represented by formula (m3);
A², A³, C, N¹ and N² are each independently a group of one or more atoms;
n3, n4 n5, n6 and n7 represent a valence of A², A³, C, N¹ and N² respectively;
n3 and n4 are each independently 1− to 5−, more preferably 1− to 3−;
n5 is 1+ to 5+, more preferably 1+ to 3+;
n6 and n7 are 0;
NA1, NB1, NC1, ND1 and NE1 are each independently 1 to 50, preferably 2 to 45;
NA2, NB2, NC2, ND2 and NE2 are each independently 1 to 55, preferably 1 to 50;
NA3, NB3, NC3, ND3, NE3, NA4, NB4, NC4, ND4 and NE4 are each independently 0 to 80, preferably 0 to 70, more preferably 0 to 65;
NA5, NB5, NC5, ND5 and NE5 are each independently 0 to 20, preferably 0 to 15, more preferably 0 to 10;
NA6, NB6, NC6, ND6, NE6, NA7, NB7, NC7, ND7 and NE7 are each independently 0 to 40, preferably 0 to 30, more preferably 0 to 20;
provided that 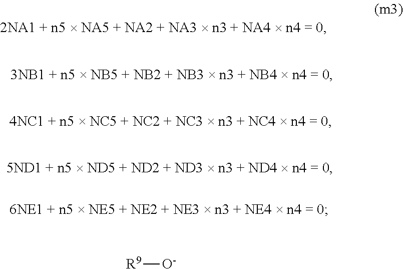
wherein
R⁹ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms; an aryl-alkylene having 6 to 25 carbon atoms, preferably from 6 to 15 carbon atoms, more preferably 6 to 10 carbon atoms;
wherein one or more non-adjacent CH₂ may each be replaced by O, S, CO, CO—O, O—CO, O—CO—O, CR¹⁰═CR¹¹, or C≡C, preferably replaced by CO, CO—O, O—CO, or O—CO—O, more preferably CO;
R¹⁰ and R¹¹ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms.

5. The formulation according to one claim 1, wherein the metal oxide precursor is represented by any one of formulae (m4-1) to (m4-5); 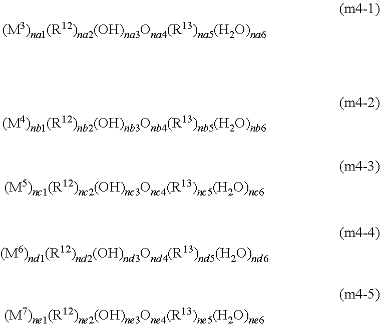
wherein
na1, nb1, nc1, nd1, and ne1 are each independently 1 to 50, preferably 2 to 45;
na2, nb2, nc2, nd2, and ne2 are each independently 1 to 55, preferably 1 to 50;
na3, nb3, nc3, nd3, and ne3 are each independently 0 to 20, preferably 0 to 10, more preferably 0 to 5;
na4, nb4, nc4, nd4, and ne4 are each independently 1 to 80, preferably 1 to 70, more preferably 1 to 65;
na5, nb5, nc5, nd5, and ne5 are each independently 0 to 20, preferably 0 to 10, more preferably 0 to 5;
na6, nb6, nc6, nd6, and ne6 are each independently 0 to 20, preferably 0 to 10, more preferably 0 to 5;
provided that 2na1=na2+na3+2na4, 3nb1=nb2+nb3+2nb4, 4nc1=nc2+nc3+2nc4, 5nd1=nd2+nd3+2nd4, 6ne1=ne2+ne3+2ne4;
M³ is Cu, Zn or Bi, preferably Zn,
M⁴ is Al,
M⁵ is Pb, Sn or Ti, preferably Ti,
M⁶ is Nb or V, preferably Nb,
M⁷ is Fe, Cr, Mo or W;
R¹² is the ligand represented by formula (m5), and
R¹³ is an acid; 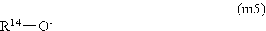
wherein
R¹⁴ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl-alkylene having 6 to 25 carbon atoms, preferably 6 to 15 carbon atoms, more preferably 6 to 10 carbon atoms;
wherein one or more non-adjacent CH₂ may each be replaced by O, S, CO, CO—O, O—CO, O—CO—O, CR¹⁵═CR¹⁶, or C≡C, preferably replaced by CO, CO—O, O—CO, or O—CO—O, more preferably CO;
R¹⁵ and R¹⁶ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms.

6. The formulation according to claim 1, the ligand stabilizes the remainder of the metal oxide precursor.

7. The formulation according to claim 1, wherein the mole ratio of the compound A to the metal oxide precursor is in the range from 0.6N_{A} to 1.4N_{A}, preferably 0.7N_{A} to 1.3N_{A}, more preferably 0.75N_{A} to 1.2N_{A}, very preferably 0.80N_{A} to 1.1N_{A}, when N_{A} represents the number of ligands contained in one metal oxide precursor.

8. The formulation according to claim 5, wherein R¹³ is an acid represented by formula (m6); 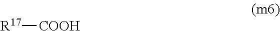
wherein
R¹⁷ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms;
wherein one or more non-adjacent CH₂ may each be replaced by O, S, CO, CO—O, O—CO, O—CO—O, CR¹⁸═CR¹⁹, or C≡C;
R¹⁸ and R¹⁹ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms.

9. The formulation according to one claim 1, further comprising a solvent selected from one or more members of the group consisting of a secondary linear or branched ≥C3 alcohol, preferably it is selected from isopropanol, 2-butanol, 2-pentanol, 3-pentanol, propylene glycol monoalkyl ethers, preferably it is propylene glycol monomethyl ether, propylene glycol monoethyl ether and/or propylene glycol monopropyl ether, propylene glycol monoalkyl ether acetates, preferably it is propylene glycol monomethyl ether acetate, propylene glycol dialkyl ethers, preferably it is propylene glycol dimethyl ether, alkyl lactate, preferably it is ethyl lactate;
wherein the solid content is preferably in the range from 0.1 to 20 mass parts, more preferably 0.5 to 15 mass parts, very preferably 0.8 to 10 mass parts based on 100 parts of the formulation.

10. The formulation according to claim 1, further comprising compound B, wherein the compound B comprises Si;
wherein the content of the compound B is preferably in the range from 7 to 50 mass parts, more preferably 10 to 40 mass parts, very preferably 15 to 30 mass parts based on 100 parts of the metal oxide precursor.

11. The formulation according to claim 10, wherein the compound B is represented by formula (c1); 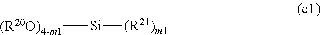
wherein
m1 is 0, 1, 2 or 3, preferably 1;
R²⁰ is a straight-chain alkyl having 1 to 15 carbon atoms, preferably 1 to 10 carbon atoms, more preferably 1 to 5 carbon atoms, very preferably 1 to 3 carbon atoms; a branched or cyclic structure-containing alkyl having 3 to 15 carbon atoms, preferably 3 to 10 carbon atoms, more preferably 3 to 5 carbon atoms; an aryl having 6 to 20 carbon atoms, preferably 6 to 15 carbon atoms, more preferably 6 to 10 carbon atoms;
wherein one or more non-adjacent CH₂ may each be replaced by O, S, CO, CO—O, O—CO, O—CO—O, CR²²═CR²³, or C≡C;
R²² and R²³ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more H may each be replaced by OH, COOH, a straight-chain alkyl having 1 to 6 carbon atoms, or a branched or cyclic structure-containing alkyl having 3 to 6 carbon atoms;
wherein R²¹ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; a straight-chain alkenyl having 1 to 25 carbon atoms, preferably 1 to 15 carbon atoms, more preferably 1 to 10 carbon atoms; a branched or cyclic structure-containing alkenyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more non-adjacent CH₂ may each be replaced by O, S, CO, CO—O, O—CO, O—CO—O, CR²⁴═CR²¹, C═CR²⁴R²¹, or C≡C, preferably replaced by O—CO;
wherein R²⁴ and R²⁵ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms, very preferably R²⁴ and R²⁵ are H;
wherein one or more H may each be replaced by OH, COOH, a straight-chain alkyl having 1 to 6 carbon atoms, or a branched or cyclic structure-containing alkyl having 3 to 6 carbon atoms.

12. (canceled)

13. A method for preparing an optical layer containing a metal oxide, preferably a particle-free optical layer containing a metal oxide, to be used for nanoimprint lithography, more preferably to be used for direct UV nanoimprint lithography, comprising the following step (i);
(i) coating the formulation according to claim 1 above a substrate to form an optical layer, preferably the substrate is a silicon wafer; preferably by spin-coating, more preferably by spin-coating with 500 to 6,000 RPM for 5 to 100 seconds, very preferably by spin-coating with 1,000 to 5,000 RPM for 10 to 70 seconds, most preferably spin-coating with 1,500 to 4,500 RPM for 15 to 50 seconds.

14. The method according to claim 13, further comprising the following step (ii);
(ii) heating the optical layer at 35 to 200° C. for 1 to 100 minutes, preferably at 40 to 150° C. for 1 to 50 minutes, more preferably at 45 to 100° C. for 1 to 20 minutes.

15. The method according to claim 13, further comprising the following step (iii);
(iii) irradiating light to the optical layer, preferably the light is UV; preferably the light intensity is in the range from 150 to 500 mW/cm², more preferably 200 to 400 mW/cm², very preferably 250 to 350 mW/cm²; preferably the wavelength of the light is in the range from 100 to 500 nm, more preferably 250 to 450 nm, very preferably 350 to 400 nm; preferably the irradiation time is in the range from 1 to 120 minutes, preferably 5 to 100 minutes, more preferably 7 to 75 minutes.

16. An optical layer, preferably a particle-free optical layer, preferably to be used for nanoimprint lithography, more preferably to be used for direct UV nanoimprint lithography, produced by the method according to claim 13, wherein the thickness of the optical layer is in the range from 1 to 700 nm, preferably from 3 to 600 nm, more preferably 5 to 500 nm, very preferably 7 to 400 nm.

17. A method for producing a patterned optical layer comprising the following steps (iv) and (v);
(iv) producing an optical layer by the method according to claim 13, and
(v) forming a pattern by pressing a mold onto the optical layer,
(vi) optionally, heating the patterned optical layer, preferably at 35 to 200° C. for 1 to 100 minutes, more preferably at 40 to 150° C. for 1 to 50 minutes, very preferably at 45 to 100° C. for 1 to 20 minutes,
(vii) optionally, irradiating light to the patterned optical layer, preferably the light is UV, preferably the light intensity is in the range from 150 to 500 mW/cm², more preferably 200 to 400 mW/cm², very preferably 250 to 350 mW/cm²; preferably the wavelength of the light is in the range from 100 to 500 nm, more preferably 250 to 450 nm, very preferably 350 to 400 nm; preferably the irradiation time is in the range from 1 to 120 minutes, preferably from 5 to 100 minutes, more preferably 7 to 75 minutes.

18. A patterned optical layer produced by the method of claim 17.

19. An optical device comprising the patterned optical layer of claim 18 and a substrate.

20. A display device comprising at least one functional medium configured to direct and modulate a light or configured to emit light; and the patterned optical layer of claim 18.

21. A display device comprising at least one functional medium configured to direct and modulate a light or configured to emit light; and the optical device of claim 19.
